(19) United States
(12) Patent Application Publication
(10) Pub. No.: US 2024/0288641 A1
(43) Pub. Date: Aug. 29, 2024

(54) Immersible Optical Module

(71) Applicant: OPTOMIND INC., Suwon-si (KR)

(72) Inventors: Hyun Ryong CHO, Suwon-si (KR); Yong Geon Lee, Hwaseong-si (KR); Yung Sung Son, Suwon-si (KR)

(21) Appl. No.: 18/173,387

(22) Filed: Feb. 23, 2023

(51) Int. Cl. G02B 6/42; H05K 7/20

(52) U.S. Cl. CPC G02B 6/4255; G02B 6/4257; H05K 7/20772

(57) ABSTRACT

The present disclosure relates to an immersible optical module. More specifically, the present disclosure relates to an immersible optical module, comprising: a substrate including an optical device; an optical assembly coupled to the substrate and forming an optical path between an optical fiber and the optical device; and a protective cap coupled to the optical assembly and including an injection hole through which an ultraviolet (UV) curable material is injected, wherein the immersible optical module is formed by injecting the UV curable material through the injection hole and radiating UV light to the UV curable material, after the substrate is coupled to the optical assembly, and then the protective cap is coupled to the optical assembly.

### BACKGROUND OF THE INVENTION

### 1. Technical Field

The present disclosure relates to an optical module, and more specifically relates to an immersible optical module.

### 2. Description of Related Art

The information described in this section merely provides the background of the present disclosure and does not constitute prior art.

A data center includes servers, storage, and network devices required to provide computing services. In order to effectively transmit the enormous amount of data traffic exchanged inside the data center, an optical interconnection solution is used between the devices.

As high-speed, high-bandwidth, and high-density devices are used in data centers, the resulting high heating has emerged as an important problem to be solved.

Existing cooling method for solving the heating problem generated in computing devices includes air cooling which dissipates heat through air as a medium or liquid cooling which dissipates heat through water or liquid as a medium. However, recently, immersion cooling with higher cooling efficiency and less carbon dioxide emission has been introduced.

Immersion cooling has an advantage of excellent cooling efficiency. However, the liquid used in cooling may be introduced to an optical path between optical devices or optical systems included in an optical module for optical connection, thereby distorting or blocking optical transmission. For example, an optical system component such as a lens or a reflector performs a function based on the difference in refractive index between the media, but there is a problem that this function may be disabled or distorted by the refractive index of the liquid used for cooling.

Accordingly, there has been a demand for an optical module capable of operating well even when immersion cooling is used, but there is a problem that the prior art cannot provide such an optical module. The present disclosure is to solve this problem.

### SUMMARY

It is an aspect of the present disclosure to provide an optical module capable of operating well even in a computing device to which immersion cooling is applied.

It is another aspect of the present disclosure to provide an optical module for preventing a liquid from being introduced to an optical path.

It is yet another aspect of the present disclosure to provide an optical module capable of operating well even in a state immersed in a liquid.

It is still yet another aspect of the present disclosure to provide an optical module capable of preventing contamination of an optical device and an optical system.

However, the aspects of the present disclosure are not limited to the aspects mentioned above, and other aspects of the present disclosure that are not mentioned herein can be understood by the description of the disclosure and can be more clearly understood by the embodiments of the present disclosure.

An immersible optical module according to an embodiment of the present disclosure for achieving the above technical task comprises: a substrate including an optical device; an optical assembly coupled to the substrate and forming an optical path between an optical fiber and the optical device; and a protective cap coupled to the optical assembly and including an injection hole through which an ultraviolet (UV) curable material is injected, wherein the immersible optical module is formed by radiating UV light to the UV curable material after coupling the protective cap to the optical assembly in a state where the substrate is coupled to the optical system and injecting the UV curable material through the injection hole.

In an embodiment, the protective cap may comprise a fixing part for coupling to the optical assembly.

In an embodiment, the fixing part may be formed by which a portion of a side surface of the protective cap is concavely formed toward the inside.

In an embodiment, the protective cap may be coupled with the optical assembly, being spaced apart by a certain space without being in direct contact with the optical assembly except for the fixing part.

In an embodiment, the UV curable material injected through the injection hole may fill the space spaced apart between the protective cap and the optical assembly.

In an embodiment, the protective cap may be made of a material capable of transmitting UV light.

In an embodiment, the protective cap may comprise an inlet through which an optical fiber is introduced into the optical assembly.

In an embodiment, the injection hole may be located on an upper surface of the protective cap.

In an embodiment, the UV curable material may comprise at least one selected from an epoxy-based composition, a silicone-based composition, a silicone acrylate-based composition, a polyacrylic-based composition, a polyether-based composition, a urethane-based composition, a polyester-based composition, and a modified acryl-based composition.

In an embodiment, the UV curable material has a viscosity of 1,000 mPa·s or more.

In an embodiment, the UV curable material has a viscosity of 1,500 mPa·s or more and 3,000 mPa·s or less.

In an embodiment, a lower surface of the optical assembly may be formed to encapsulate an area where the optical devices of the substrate are located.

In an embodiment, the UV curable material injected through the injection hole may seal the encapsulated area.

In an embodiment, the optical assembly may comprise a body and a cover.

According to an embodiment of the present disclosure, an optical module capable of operating well even in a computing device to which immersion cooling is applied may be provided.

According to an embodiment of the present disclosure, an optical module for preventing a liquid from being introduced to an optical path may be provided.

According to an embodiment of the present disclosure, an optical module capable of operating well even in a state immersed in a liquid may be provided.

According to an embodiment of the present disclosure, an optical module capable of preventing contamination of an optical device and an optical system may be provided.

In addition to the above, specific effects of the present disclosure will be described together while explaining specific details of the present disclosure in the following.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a conceptual diagram illustrating a system for removing heat generated from devices such as servers in a data center using immersion cooling;

FIG. 2 is an exploded perspective view of an optical module according to an embodiment of the present disclosure;

FIG. 3 is an exploded perspective view of an optical module in which an optical assembly is coupled to a substrate according to an embodiment of the present disclosure;

FIG. 4 is a perspective view of a coupled optical module according to an embodiment of the present disclosure;

FIG. 5 is a perspective view of the coupled optical module in FIG. 4, transparently illustrating the protective cap;

FIG. 6 is a perspective view illustrating a lower surface of an optical assembly according to an embodiment of the present disclosure;

FIG. 7 is a diagram illustrating a lower surface of a substrate according to an embodiment of the present disclosure;

FIG. 8 is a perspective view illustrating an optical module in which an optical assembly is coupled to a substrate according to an embodiment of the present disclosure;

FIG. 9 is a perspective view transparently illustrating the body of the optical assembly in FIG. 8;

FIG. 10 is a perspective view of a protective cap according to an embodiment of the present disclosure;

FIG. 11A is a top view of a protective cap according to an embodiment of the present disclosure;

FIG. 11B is a bottom view of a protective cap according to an embodiment of the present disclosure;

FIG. 12A is a front view of a protective cap according to an embodiment of the present disclosure;

FIG. 12B is a back view of a protective cap according to an embodiment of the present disclosure; and

FIG. 12C is a side view of a protective cap according to an embodiment of the present disclosure.

### DETAILED DESCRIPTION

In order to clarify the technical idea of the present disclosure, embodiments of the present disclosure will be described in detail with reference to the accompanying drawings. In describing the present disclosure, if it is determined that a detailed description of a related known function or component may unnecessarily obscure the subject matter of the present disclosure, detailed description thereof will be omitted. Components having substantially the same functional configuration in the drawings are given the same reference numerals and symbols as much as possible, even if they are displayed on different drawings. For the sake of convenience in description, a device and method are described together, if necessary. Each operation of the present disclosure does not necessarily have to be performed in the order described, and may be performed in parallel, selectively, or separately.

The terms used in the embodiments of the present disclosure have been selected from general terms that are currently widely used as much as possible in consideration of the function in the present disclosure, but they may vary depending on the intention of a person skilled in the art or precedents, the emergence of new technologies, and the like. In addition, in a specific case, there may also be terms arbitrarily selected by the applicant, and in this case, the meanings thereof will be described in detail in the description of the corresponding embodiments. Therefore, the terms used in this specification should be defined based on the meanings of the terms and the overall content of the present disclosure, not simply based on the names of the terms.

Throughout the present disclosure, singular expressions may include plural expressions unless the context clearly specifies otherwise. Terms such as “include” or “have” are intended to designate that a feature, number, step, operation, component, part, or combination thereof exists, not to exclude the possibility of the presence or addition of one or more other features, numbers, steps, operations, components, parts or combinations thereof. In other words, throughout the present disclosure, when a certain part “includes” a certain component, it means that other components may be further included rather than excluding other components, unless otherwise specified.

The expression “at least one” modifies the list of elements as a whole and does not modify the elements of the list individually. For example, “at least one of A, B, and C” and “at least one of A, B, or C” means A alone, B alone, C alone, both A and B, both B and C, both A and C, A, B, and C all together, or a combination thereof.

In addition, terms such as “ . . . unit” and “ . . . module” described in the present disclosure refer to a unit that processes at least one function or operation, which may be implemented as hardware or software or a combination of hardware and software.

Throughout the present disclosure, when a part is “connected” to another part, this includes not only the case where a part is “directly connected” to another part, but also the case where it is “electrically connected” with another element in between. In addition, when a part “includes” a certain component, it means that other components may be further included rather than excluding other components, unless otherwise specified.

The expression “configured to” used throughout the present disclosure may be interchangeably used with terms such as “suitable for,” “having the capacity to,” “designed to,” “adapted to,” “made to,” or “capable of” depending on the situation. The term “configured to” may not necessarily mean only “specifically designed to” in hardware. Instead, in some contexts, the expression “a system configured to” may mean that the system is “capable of” doing something in conjunction with other devices or components. For example, the phrase “a processor configured to perform A, B and C” may refer to a dedicated processor (e.g., embedded processor) for performing a corresponding operation, or a generic-purpose processor (e.g., CPU or application processor) capable of performing corresponding operations by executing one or more software programs stored in the memory.

In addition, throughout the present disclosure, parts expressed in singular or plural form may be construed as including both singular and plural cases except for indispensable cases. In addition, terms such as “first” and “second” are used only as terms for distinguishing one component from another, and the scope of right should not be limited by these terms.

Hereinafter, preferred embodiments according to the present disclosure will be described in detail with reference to the accompanying drawings.

Before describing the present disclosure, the following specific structural or functional descriptions are merely illustrative for the purpose of describing embodiments according to the concept of the present disclosure. Embodiments according to the concept of the present disclosure may be implemented in various forms, and should not be construed as being limited to the embodiments described herein.

In addition, since embodiments according to the concept of the present disclosure may be subject to various changes and may have various forms, specific embodiments are illustrated in the drawings and described in detail herein. However, it should be understood that the embodiments according to the concept of the present disclosure are not intended to limit the present disclosure to a specific disclosure form, but include all modifications, equivalents and alternatives falling within the spirit and scope of the present disclosure.

The present disclosure relates to an optical module, and more particularly relates to an immersible optical module capable of operating well even in an immersed state.

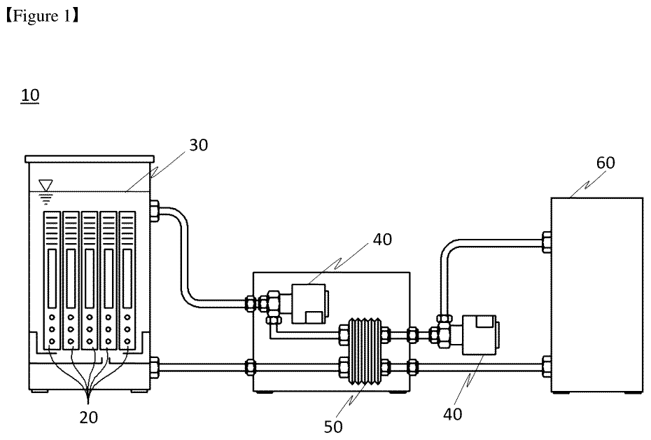

FIG. 1 is a conceptual diagram illustrating a system for removing heat generated from devices such as servers in a data center using immersion cooling.

Referring to FIG. 1, immersion cooling is a method of cooling a device 30 such as a server, storage, network device, etc., by fully submerging the device in a liquid 40 which is thermally conductive but electrically insulating. Immersion cooling is efficient because the electrically insulating liquid 40 is in direct contact with hot components and can effectively absorb thermal energy, and the liquid more easily moves than air. The liquid 40 used in immersion cooling can be circulated mechanically (using a circulation pump 50) or naturally, so as to be used again for immersion cooling after lowering the temperature through a heat exchanger 60 or a cooling system. The fluid used in heat exchange with the electrically insulating liquid 40 may be cooled in the cooling system 70 using the circulation pump 50.

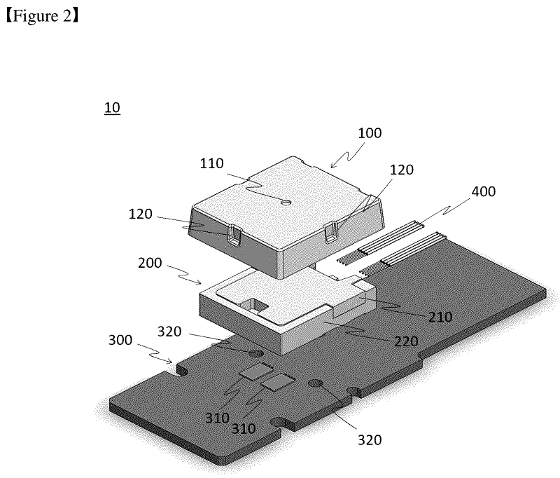

FIG. 2 is an exploded perspective view of an optical module 10 according to an embodiment of the present disclosure.

Referring to FIG. 2, the optical module 10 according to an embodiment of the present disclosure may comprise a protective cap 100, an optical assembly 200 and a substrate 300. The optical assembly 200 may be coupled to the substrate 300, and form an optical path between an optical fiber 400 and an optical device 310 of the substrate. The protective cap 100 may be coupled to the optical assembly 200, and include an injection hole 110 through which an ultraviolet (UV) curable material is injected into the protective cap 100.

According to an embodiment, the substrate 300 may comprise an optical device 310, and the optical device 310 comprises at least one of an electro-optical conversion device and a photoelectric conversion device. Here, an electro-optical conversion device refers to a device converting an electrical signal into an optical signal, and for example, includes light-emitting diode (LED), vertical-cavity surface emitting laser (VCSEL), etc. Aphotoelectric conversion device refers to a device converting an optical signal into an electrical signal, and for example, includes photodiode (PD), avalanche photodiode (APD), etc.

According to an embodiment, the optical device 310 included in the substrate 300 comprises at least one of an electro-optical conversion device and a photoelectric conversion device, thereby enabling conversion between an electrical signal and an optical signal.

According to an embodiment, the substrate 300 may comprise an electronic device (not shown) in addition to the optical device 310. The electronic device is electrically connected to the optical device 310 to drive the optical device 310. For example, the electronic device may be configured using a driver IC (integrated circuit). In addition, the electronic device may comprise a transimpedance amplifier (TIA) to amplify the current of the electrical signal converted from the photoelectric conversion device to a high voltage.

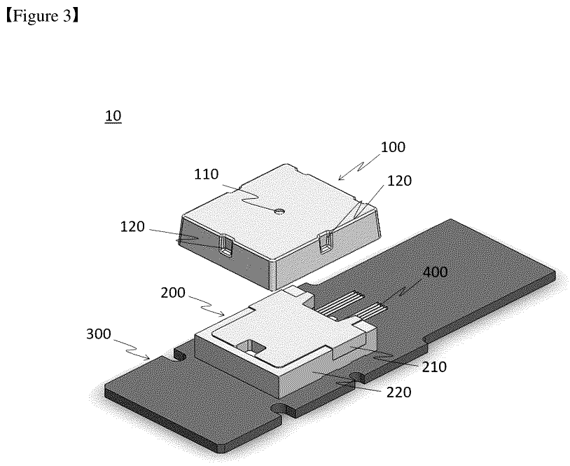

FIG. 3 is an exploded perspective view of an optical module 10 in which an optical assembly 200 is coupled to a substrate 300 according to an embodiment of the present disclosure.

According to an embodiment, the optical assembly 200 may be coupled to the substrate 300, and form an optical path between an optical device 310 of the substrate 300 and an optical fiber 400. The optical assembly 200 may comprise a reflector and a lens to form an optical path. For example, the lens may include a focusing lens or a collimator lens, and a prism may be used as the reflector.

According to an embodiment, the optical assembly 200 may be formed using a synthetic resin by injection molding or a 3D printing process, and the direction or shape of light is changed to optically couple the optical fiber 400 connected to the outside and the optical device 310. For example, it may be understood that the optical assembly 200 changes the direction and shape of the beam, which is a directional light energy emitted from the optical device 310. To this end, the optical assembly 200 may comprise a lens and a reflector.

According to an embodiment, the optical assembly 200 may comprise a cover 210 and a body 220, and the cover 210 and the body 220 are coupled to each other. In an embodiment, the optical assembly 200 may form an optical path between the optical fiber 400 and the optical device 310 of the substrate 300 by coupling the cover 210 and the body 220.

According to an embodiment, the optical module 10 is connected to the outside through an optical fiber 400. That is, the optical fiber 400 may be optically connected to another optical module separate from the optical module 10 according to an embodiment of the present disclosure. Here, the optical fiber 400 may be connected to an optical device 310 through the optical assembly 200 of the optical module 10.

According to an embodiment, the optical assembly 200 of the optical module 10 according to an embodiment of the present disclosure may comprise at least one optical fiber 400. The optical fiber 400 comprises a core and a cladding. The optical fiber 400 may comprise a core and a cladding with distinct refractive indices, but may also comprise a material whose refractive index gradually changes. In addition, in order to protect the core and cladding of the optical fiber 400 from an external impact or damage, a sheath may be further formed outside the cladding.

According to an embodiment, the optical fiber 400 may be made of high-purity glass or synthetic resin. Typically, the refractive index of the core is greater than the refractive index of the cladding. By making the refractive index of the core greater than the refractive index of the cladding, the light incident on the core of the optical fiber 400 may be transmitted far without being lost to the outside while being totally reflected at the boundary surface between the core and the cladding. Here, the optical fiber 400 comprises not only glass optical fibers used for long-distance optical communication, but also various types of optical waveguide structures for optical signal transmission, e.g., a polymer optical waveguide manufactured using a polymer.

In an embodiment, there may be one or a plurality of optical fibers 400. When there are a plurality of optical fibers 400, some of the plurality of optical fibers 400 may be transmission optical fibers which transmit optical signals, and the others may be receiver optical fibers which receive optical signals, but the optical fibers are not necessarily limited thereto.

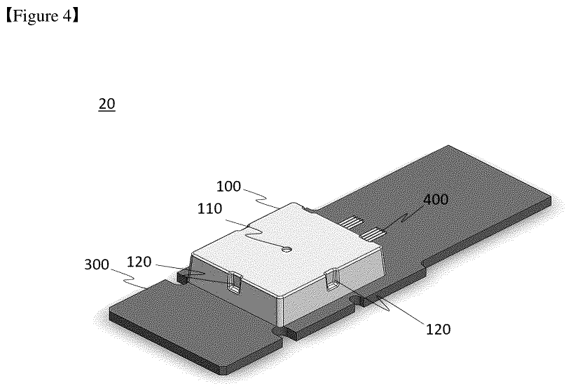

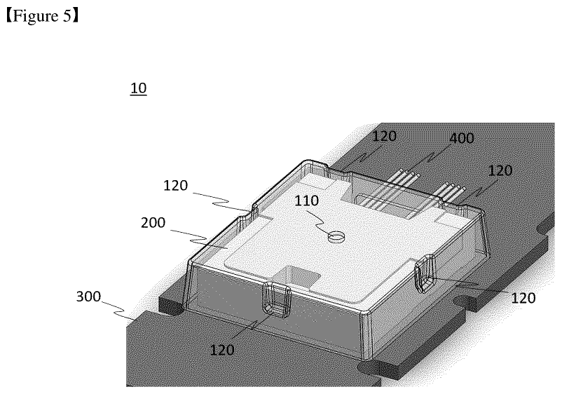

FIG. 4 is a perspective view of a coupled optical module 10 according to an embodiment of the present disclosure. FIG. 5 is a perspective view of the coupled optical module in FIG. 4, transparently illustrating the protective cap 100.

In an embodiment, the protective cap 100 may be coupled to the optical assembly 200. In addition, the protective cap 100 may comprise a fixing part 120 for coupling to the optical assembly 200. For example, the fixing part 120 of the protective cap 100 is a concave part concavely formed toward the inside of the protective cap 100. When the protective cap 100 is coupled to the optical assembly 200, the fixing part 120 may be fit-coupled to the outer surface of the optical assembly 200.

Referring to FIGS. 2, 4, and 5, for example, the protective cap 100 is a rectangular box without a lower surface, and has at least one fixing part 120 (concavely formed toward the inside) formed on the front, rear, left and right surfaces, respectively. When coupled to the optical assembly 200, the fixing part 120 may be fit-coupled to the outer surface of the optical assembly 200. For example, the optical assembly 200 may be coupled to the substrate 300 after coupling the protective cap 100 to the optical assembly 200. As another example, the protective cap 100 may be coupled to the optical assembly 200 after coupling the optical assembly 200 to the substrate 300.

In an embodiment, the protective cap 100 is coupled with the optical assembly 200, being spaced apart by a certain space without being in direct contact with the optical assembly 200. For example, referring to FIG. 5, the protective cap 100 has a larger size than the optical assembly 200. However, the fixing part 120 is formed concavely in the inward direction such that the fixing part 120 may be fit-coupled to the outer surface of the optical assembly 200. Thus, a certain empty space exists between the inside of the protective cap 100 and the optical assembly 200.

In an embodiment, the protective cap 100 may comprise an injection hole 110 through which a UV curable material may be injected. The UV curable material may be injected through the injection hole 110 of the protective cap 100 after the protective cap 100, the optical assembly 200, and the substrate 300 are coupled. For example, the UV curable material may be injected through the injection hole 110 of the protective cap 100 using gravity. As another example, the UV curable material may be injected through the injection hole 110 of the protective cap 100 using artificial or mechanical pressure. As another example, a UV curable material may be injected through the injection hole 110 of the protective cap 100 using an automatic injection device (not shown).

In an embodiment, the UV curable material injected through the injection hole 110 of the protective cap 100 fills a certain empty space between the inside of the protective cap 100 and the optical assembly 200, and then the UV curable material is cured by radiating UV light, so as to prevent the invasion of liquid into the optical assembly 200.

In an embodiment, the UV curable material may be cured by radiating UV light after injecting a UV curable material into the protective cap 100. The protective cap 100 may be made of a material capable of transmitting UV light. For example, the protective cap 100 may be made of a transparent material.

In an embodiment, the UV curable material may have a viscosity of 1,000 to 3,000 mPa·s. According to experimental results, when the viscosity of the UV curable material is less than 1,000 mPa·s, there was a problem that the UV curable material penetrates into the optical assembly 200, and when the viscosity of the UV curable material is 3,000 mPa·s or more, there was a problem that the UV curable material did not flow well into the space between the optical assembly 200 and the protective cap 100. In an embodiment, preferably, the UV curable material has a viscosity of about 1,500 to 3,000 mPa·s.

In an embodiment, the UV curable material may comprise at least one selected from an epoxy-based composition, a silicone-based composition, a silicone acrylate-based composition, a polyacrylic-based composition, a polyether-based composition, a urethane-based composition, a polyester-based composition, and a modified acryl-based composition.

In an exemplary embodiment, the UV curable material may include a UV polymerizable oligomer and a photopolymerization initiator.

For example, the UV polymerizable oligomer may include one or more selected from a modified acrylic-based oligomer, a polyester-based oligomer, an epoxy-based oligomer, an urethane-based oligomer, a polyether-based oligomer, a polyacrylic-based oligomer, a silicon acrylate-based oligomer, and the like, and the photopolymerization initiator may include one or more selected from a benzoin ether-based compound, amines compounds, an α-hydroxy ketone-based compound, a phenyl glyoxylate-based compound, an acyl phosphineoxide-based compound, and the like.

In an exemplary embodiment, the UV curable material may further include a diluent. The diluent may control the viscosity of the adhesive composition and improve a property of the UV curable material after curing. The diluent may include one or more selected from a styrene monomer, a methylmethacrylate monomer, an ethylmethacrylate monomer, an n-butylmethacrylate monomer, an iso-butylmethacrylate monomer, a t-butylmethacrylate monomer, a vinylchloride monomer, a vinylacetate monomer, an acrylonitrile monomer, a 2-ethylhexylmethacrylate monomer, a laurylmethacrylate monomer, a methylacrylate monomer, an ethylacrylate monomer, an n-butylacrylate monomer, an iso-butylacrylate monomer, a 2-ethylhexylacrylate monomer, an ethylene monomer, an octadecylmethacrylate monomer, and the like, or one or more selected from acrylic acid, methacrylic acid, 2-hydroxyethylmethacrylate, 2-hydroxypropylmethacrylate, dimethylaminoethylmethacrylate, t-butylaminoethylmethacrylate, diethylaminoethylmethacrylate, glycidylmethacrylate, 2-hydroxyethylacrylate, 2-hydroxypropylacrylate, itaconic acid, maleicacid, acrylamide, N-methylolacrylamide, and the like.

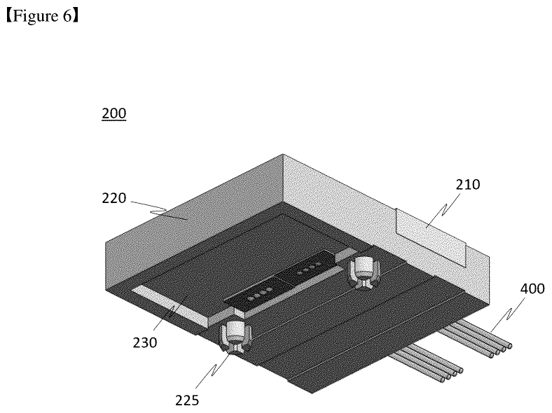

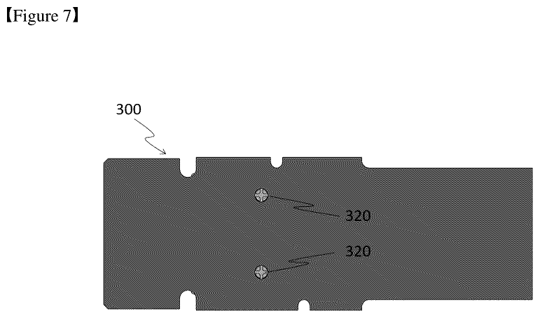

FIG. 6 is a perspective view illustrating a lower surface of an optical assembly 200 according to an embodiment of the present disclosure. FIG. 7 is a diagram illustrating a lower surface of a substrate 300 according to an embodiment of the present disclosure.

Referring to FIG. 6, a coupling pin 225 which may be used for coupling to the substrate 300 may be formed in a lower surface of the optical assembly 200 according to an embodiment. For example, the coupling pin 225 may be formed in a cylindrical shape with the center split in the shape of a cross as illustrated in FIG. 6. Also, the coupling pin 225 of the optical assembly 220 may be coupled to a coupling hole 320 of the substrate 300 (illustrated in FIG. 2).

Referring to FIG. 7, even when a coupling pin 225 of the optical assembly 200 is coupled to a coupling hole 320 of the substrate 300, the coupling hole 320 may not be completely sealed depending on the shape of the coupling pin 225. In this case, the invasion of liquid may be allowed through the coupling hole 320. In order to prevent this, the coupling hole 320 may be cured by radiating UV light after applying a UV curable material to the coupling hole 320. Through this process, the coupling hole 320 may be sealed so that liquid does not invade the optical assembly 200 through the coupling hole 320.

Referring to FIG. 6, the optical assembly 200 according to an embodiment may comprise an encapsulation area 230 on a lower surface. In an embodiment, as illustrated in FIG. 6, the encapsulation area 230 of the optical assembly 200 is an area where the outer circumferential part is coupled to the substrate while being in contact therewith, and the center part is spaced apart from the substrate to form a space. In an embodiment, when the optical assembly 200 is coupled to the substrate 300, the optical device 310 of the substrate 300 is located in the encapsulation area 230 of the optical assembly 200, and an optical path connected from the optical device 310 to the optical assembly 200 is formed in the encapsulation area 230.

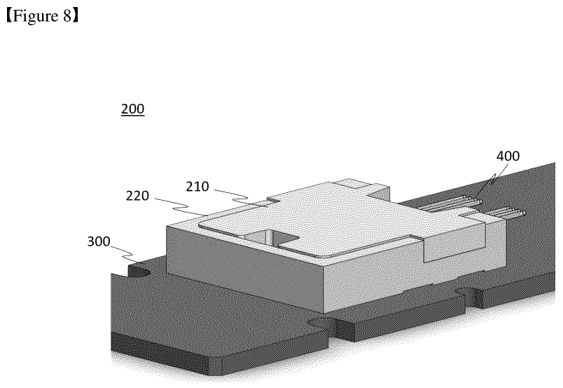

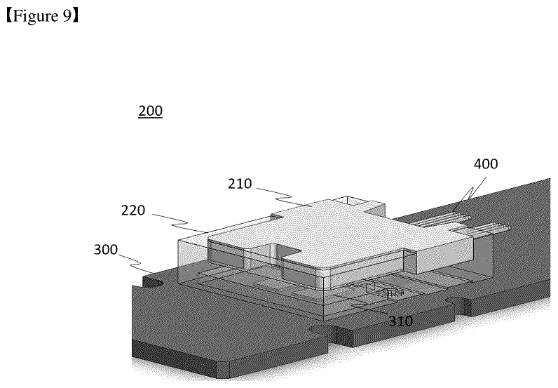

FIG. 8 is a perspective view illustrating an optical module in which an optical assembly 200 is coupled to a substrate 300 according to an embodiment of the present disclosure. FIG. 9 is a perspective view transparently illustrating the body 220 of the optical assembly 200 of FIG. 8.

In an embodiment, referring to FIGS. 8 and 9, the optical device 310 is located in the encapsulation area 230 of the optical assembly 200, and an optical path connected from the optical device 310 to the optical assembly 200 is formed in the encapsulation area 230.

In an embodiment, when a UV curable material is injected through an injection hole 110 of the protective cap 100, the UV curable material fills the space between the protective cap 100 and the optical assembly 200, and the UV curable material is cured by radiating UV light. Referring to FIGS. 5, 8 and 9, the UV curable material is filled up to a part where the substrate 300 and the optical assembly 200 come into contact, and when the UV curable material is cured using UV light, the substrate 300 and the optical assembly 200 are coupled by the UV curable material. Accordingly, the encapsulation area 230 of the optical assembly 200 is completely sealed by the UV curable material, and becomes impervious to liquid. Eventually, the optical path connected from the optical device 310 to the optical assembly 200 is blocked from the outside and sealed in the encapsulation area 230. As a result, the optical path inside the optical module 10 becomes impervious to liquid, and the components of the optical devices or optical systems configuring the optical path may be prevented from being contaminated from the outside.

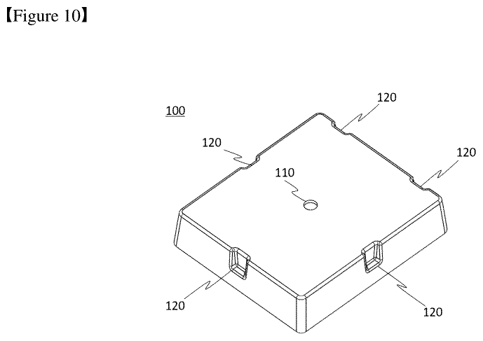

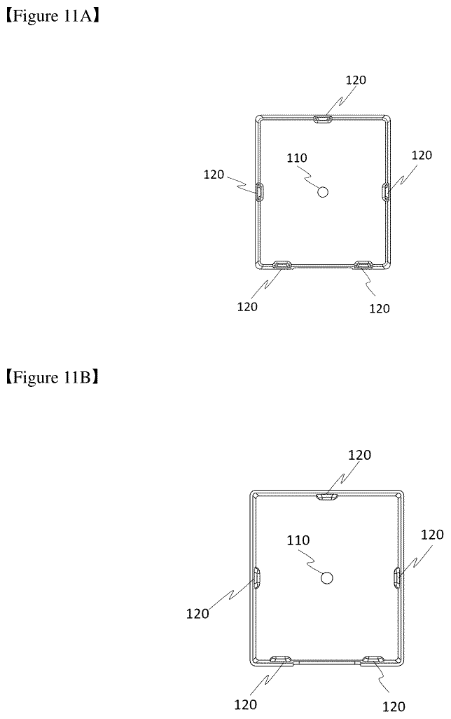

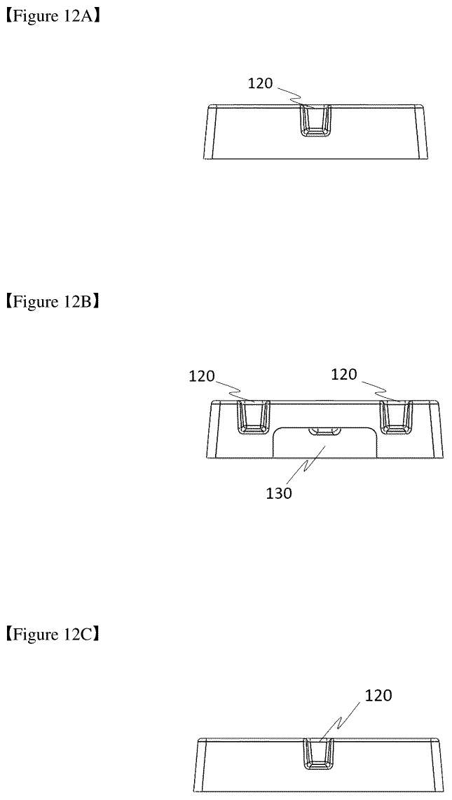

FIG. 10 is a perspective view of a protective cap 100 according to an embodiment of the present disclosure. FIG. 11A is a top view of a protective cap 100 according to an embodiment of the present disclosure. FIG. 11B is a bottom view of a protective cap 100 according to an embodiment of the present disclosure. FIG. 12A is a front view of a protective cap 100 according to an embodiment of the present disclosure. FIG. 12B is a back view of a protective cap 100 according to an embodiment of the present disclosure. FIG. 12C is a side view of a protective cap 100 according to an embodiment of the present disclosure.

In an embodiment, referring to FIG. 12B, the back surface of the protective cap 100 may comprise an introduction port 130 for introducing an optical fiber 400. For example, the optical fiber 400 may be introduced into the optical assembly 200 through the introduction port 130 of the protective cap 100.

In an embodiment, when a UV curable material is injected through an injection hole 110 of the protective cap 100, the UV curable material fills the introduction port 130 of the protective cap 100, and when the UV curable material is cured by UV light, it seals the introduction port 130 of the protective cap 100 while fixing the optical fiber 400.

The foregoing description is merely illustrative of the technical idea of the present disclosure, and various changes and modifications may be made by those skilled in the art without departing from the essential characteristics of the present disclosure. Therefore, the embodiments disclosed in the present disclosure are intended to illustrate rather than limit the scope of the present disclosure, and the scope of the technical idea of the present disclosure is not limited by these embodiments. The scope of protection of the present disclosure should be construed according to the following claims, and all technical ideas within the scope of equivalents should be construed as falling within the scope of the present disclosure.

What is claimed is:

1. An immersible optical module, comprising:
a substrate including an optical device;
an optical assembly coupled to the substrate and forming an optical path between an optical fiber and the optical device; and
a protective cap coupled to the optical assembly and including an injection hole through which an ultraviolet (UV) curable material is injected,
wherein the immersible optical module is formed by injecting the UV curable material through the injection hole and radiating UV light to the UV curable material, after the substrate, the optical assembly and the protective cap are coupled.

2. The immersible optical module of claim 1, wherein the protective cap comprises a fixing part for coupling to the optical assembly.

3. The immersible optical module of claim 2, wherein the fixing part is formed by which a portion of a side surface of the protective cap is concavely formed toward the inside.

4. The immersible optical module of claim 2, wherein the protective cap is coupled with the optical assembly, being spaced apart by a certain space without being in direct contact with the optical assembly except for the fixing part.

5. The immersible optical module of claim 4, wherein the UV curable material injected through the injection hole fills the space spaced apart between the protective cap and the optical assembly.

6. The immersible optical module of claim 1, wherein the protective cap is made of a material capable of transmitting UV light.

7. The immersible optical module of claim 1, wherein the protective cap comprises an inlet through which an optical fiber is introduced into the optical assembly.

8. The immersible optical module of claim 1, wherein the injection hole is located on an upper surface of the protective cap.

9. The immersible optical module claim 1, wherein the UV curable material comprises at least one selected from an epoxy-based composition, a silicone-based composition, a silicone acrylate-based composition, a polyacrylic-based composition, a polyether-based composition, a urethane-based composition, a polyester-based composition, and a modified acryl-based composition.

10. The immersible optical module of claim 1, wherein the UV curable material has a viscosity of 1,000 mPa·s or more.

11. The immersible optical module of claim 1, wherein the UV curable material has a viscosity of 1,500 mPa·s or more and 3,000 mPa·s or less.

12. The immersible optical module of claim 1, wherein a lower surface of the optical assembly is formed to encapsulate an area where the optical devices of the substrate are located.

13. The immersible optical module of claim 12, wherein the UV curable material injected through the injection hole seals the encapsulated area.

14. The immersible optical module of claim 1, wherein the optical assembly comprises a body and a cover.
